(19) United States
(12) Patent Application Publication
(10) Pub. No.: US 2013/0286625 A1
(43) Pub. Date: Oct. 31, 2013

(54) PORTABLE APPARATUS

(71) Applicant: PEGATRON CORPORATION, Taipei City (TW)

(72) Inventor: Chien-Min HUANG, TAIPEI CITY (TW)

(73) Assignee: PEGATRON CORPORATION, TAIPEI CITY (TW)

(21) Appl. No.: 13/775,971

(22) Filed: Feb. 25, 2013

(30) Foreign Application Priority Data
Apr. 30, 2012 (TW) 101115398

(51) Int. Cl. H05K 5/00

(52) U.S. Cl. CPC H05K 5/0086
USPC 361/809

(57) ABSTRACT

A portable apparatus includes a casing, a plastic holder and a touch pad. The casing has a fixing area, and a plurality of first through holes and at least a second through hole are formed around the fixing area. The plastic holder is disposed at the fixing area and has a plurality of first pillars and at least a second pillar. The first pillars are correspondingly disposed through the first through holes, respectively, and the second pillar is correspondingly disposed through the second through hole. The touch pad is connected with the plastic holder.

### CROSS REFERENCE TO RELATED APPLICATIONS

This Non-provisional application claims priority under 35 U.S.C. §119(a) on Patent Application No(s). 101115398 filed in Taiwan, Republic of China on Apr. 30, 2012, the entire contents of which are hereby incorporated by reference.

### BACKGROUND OF THE INVENTION

1. Field of Invention

The present invention relates to a portable apparatus and, in particular, to a portable apparatus with improved touch pad assembling.

2. Related Art

As the progress of information technology, it is desired to retrieve information timely and conveniently, and the advanced communication requirement becomes more critical. The portable consuming electronic apparatuses of various functions are continuously developed for satisfying our demands so as to make our lives more convenient.

Regarding to a notebook, it is usually configured with a touch pad and two buttons for controlling the movement and action of the cursor. Recently, a click pad, which integrates the functions of the touch pad and buttons, has been invented for making the appearance of the notebook simpler and pretty, thereby enhancing the product competitiveness.

The click pad, however, is easily deformed, so it is necessary to attach a reinforced glass layer on the surface of the click pad. Then, the click pad configured with the reinforced glass layer is installed on the casing of the notebook. The reinforced glass layer can not only protect the click pad but also support the click pad to prevent the undesired deformation thereof. However, the reinforced glass layer is very expensive, so the manufacturing cost of the portable apparatus will be increased accordingly.

### SUMMARY OF THE INVENTION

An objective of the present invention is to provide a portable apparatus with lower cost but still having the same appearance and touch control function as the conventional click pad.

To achieve the above objective, the present invention discloses a portable apparatus including a casing, a plastic holder and a touch pad. The casing has a fixing area, and a plurality of first through holes and at least a second through hole are formed around the fixing area. The plastic holder is disposed at the fixing area and has a plurality of first pillars and at least a second pillar. The first pillars are correspondingly disposed through the first through holes, respectively, and the second pillar is correspondingly disposed through the second through hole. The touch pad is connected with the plastic holder.

In one embodiment, the first pillars and the second pillar are disposed on a bottom surface of the plastic holder.

In one embodiment, the touch pad is connected to a bottom surface of the plastic holder.

In one embodiment, the plastic holder is fastened to the casing via the first pillars by thermal bonding.

In one embodiment, the fixing area further has an opening, and the first through holes and the second through hole are disposed adjacent to the opening.

In one embodiment, the touch pad passes through the opening.

In one embodiment, the portable apparatus is an ultrabook, a notebook, a smart phone, a digital camera, a PDA, or a GPS.

As mentioned above, the portable apparatus of the invention is configured with a fixing area, and a plurality of first through holes and at least a second through hole are formed around the fixing area. The plastic holder is disposed at the fixing area and has a plurality of first pillars and at least a second pillar. The first pillars are correspondingly disposed through the first through holes, respectively, and the second pillar is correspondingly disposed through the second through hole. The touch pad is connected with the plastic holder. Accordingly, the portable apparatus of the invention is not configured with the conventional reinforced glass layer, but the appearance thereof is as simple and beautiful as the conventional art, while the touch control function thereof is the same as the conventional art. Moreover, the plastic holder has lower cost. As a result, the portable apparatus of the invention has lower cost but still has the same appearance and touch control function as the conventional click pad.

These and other features, aspects and advantages of the present disclosure will become better understood with regard to the following description, appended claims, and accompanying drawings.

### BRIEF DESCRIPTION OF THE DRAWINGS

FIGS. 1 and 2 are exploded views in different viewing angles of a portable apparatus according to a preferred embodiment of the invention; and

FIGS. 3 and 4 are schematic diagrams in different viewing angles of the portable apparatus according to the preferred embodiment of the invention.

### DETAILED DESCRIPTION OF THE INVENTION

The present invention will be apparent from the following detailed description, which proceeds with reference to the accompanying drawings, wherein the same references relate to the same elements.

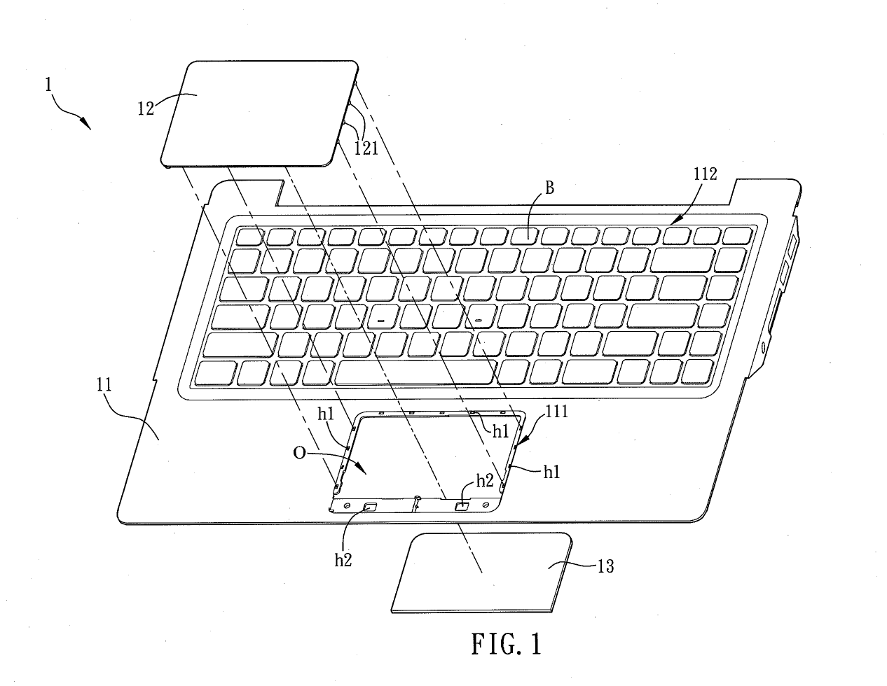

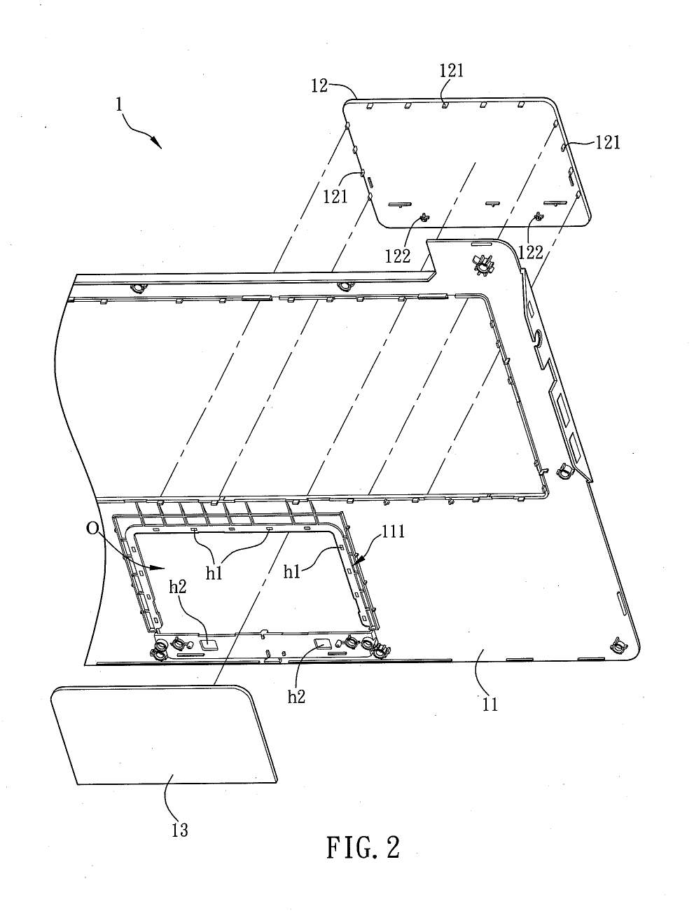

FIGS. 1 and 2 are exploded views in different viewing angles of a portable apparatus 1 according to a preferred embodiment of the invention. Herein, FIG. 1 is a top view of the portable apparatus 1, and FIG. 2 is a bottom view of the portable apparatus 1. For example, the portable apparatus 1 of the invention can be an ultrabook, a notebook, a smart phone, a digital camera, a PDA, or a GPS. In this embodiment, the portable apparatus 1 of the invention is an ultrabook.

Referring to FIG. 1, the portable apparatus 1 includes a casing 11, a plastic holder 12 and a touch pad 13.

The casing 11 has a fixing area 111, and a plurality of first through holes h1 and at least a second through hole h2 are formed around the fixing area 111. As shown in FIGS. 1 and 2, the casing 11 is a top casing of an ultrabook, and the fixing area 111 is located on one side of the casing 11. The periphery of the fixing area 111 is configured with 12 first through holes h1 and two second through holes h2. In addition, the fixing area 111 further includes an opening O, and the first through holes h1 and the second through holes h2 are disposed adjacent to the opening O for installing a touch pad and two buttons, which form a click pad of the ultrabook to control the cursor. The first through holes h1 are configured to fasten the plastic holder 12, and the two second through holes h2 are configured to install two buttons (e.g. left and right click buttons). The portable apparatus 1 includes a switch control circuit (not shown) corresponding to these buttons and electrically connecting to a control circuit board of the portable apparatus 1. Alternatively, in another embodiment, only a single second through hole h2 is configured, so that one button and one corresponding switch control circuit are configured. This invention is not limited to the above examples.

As shown in FIG. 1, the casing 11 further includes a button area 112 disposed adjacent to the fixing area 111. The button area 112 contains a plurality of buttons B. The portable apparatus 1 includes a control switch circuit (not shown) corresponding to the buttons B and electrically connecting to a control circuit board of the portable apparatus 1 for operating the portable apparatus 1.

Referring to FIG. 2, the plastic holder 12 is disposed at the fixing area 111 and has a plurality of first pillars 121 and at least a second pillar 122. The first pillars 121 are correspondingly disposed through the first through holes h1, respectively, and the second pillar 122 is correspondingly disposed through the second through hole h2. Herein, the plastic holder 12 is made of a plastic material, so it is cheaper. In this embodiment, the plastic holder 12 has 12 first pillars 121 and two second pillars 122. The first pillars 121 and second pillars 122 are disposed on the bottom surface of the plastic holder 12. Moreover, the positions of the first pillars 121 are configured corresponding to that of the first through holes h1, and the positions of the second pillars 122 are configured corresponding to that of the second through holes h2.

The touch pad 13 is connected to the plastic holder 12. In this embodiment, the touch pad 13 passes through the opening O and then connects to the bottom surface of the plastic holder 12. The touch pad 13 can be electrically connected to the control circuit board of the portable apparatus 1 for operating the portable apparatus 1.

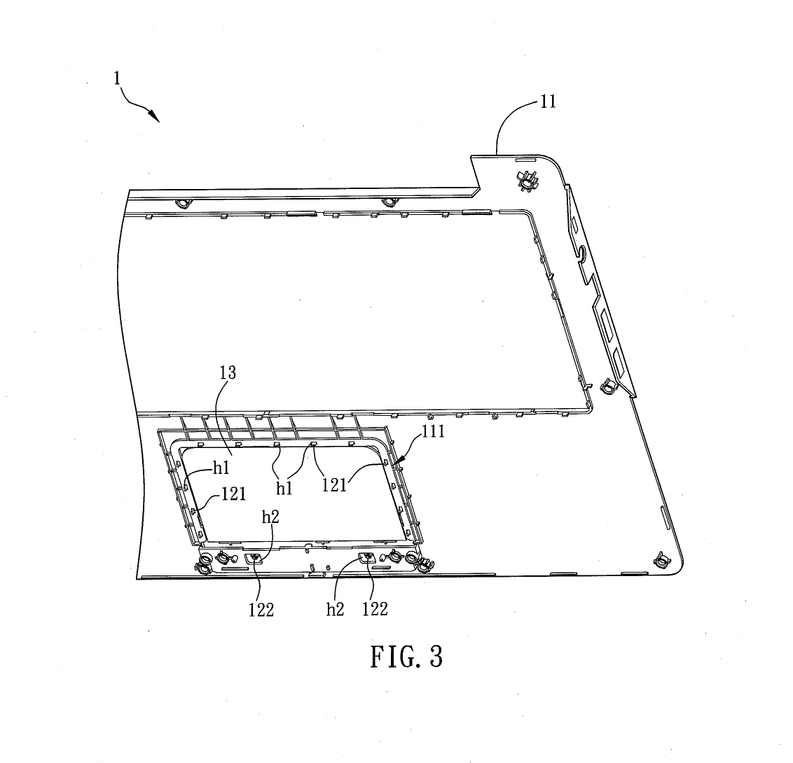

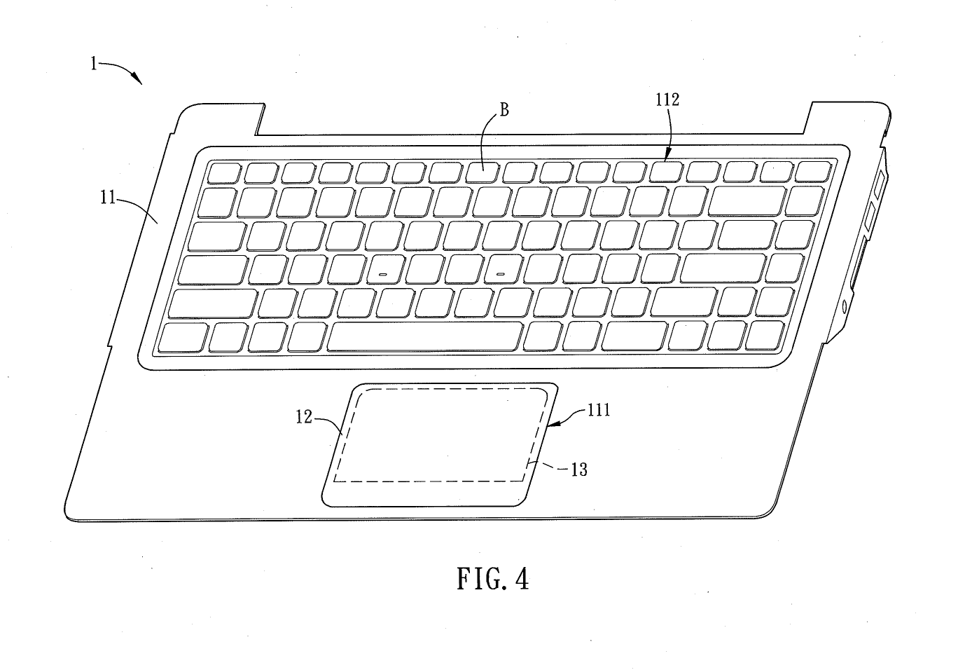

FIGS. 3 and 4 are schematic diagrams in different viewing angles of the portable apparatus 1 according to the preferred embodiment of the invention. Herein, FIG. 3 is a top view of the portable apparatus 1, and FIG. 4 is a bottom view of the portable apparatus 1.

Referring to FIGS. 2 and 3, to installing the plastic holder 12 and the touch pad 13, the first pillars 121 of the plastic holder 12 are aligned and pass through the first through holes h1 of the fixing area 111, while the second pillars 122 are aligned and pass through the second through holes h2. Afterwards, the first pillars 121 are heated to melt so as to fasten the plastic holder 12 on the fixing area 111 of the casing 11, thereby installing and fixing the plastic holder 12 at the fixing area 111. Of course, it is possible to apply an adhesive to enhance the connection therebetween. Finally, the touch pad 13 is attached to the bottom surface of the plastic holder 12 through the opening O so as to finish the installation of the click pad of the portable apparatus 1.

With reference to FIG. 4, the plastic holder 12 is installed at the fixing area 111, and the touch pad 13 is connected to the bottom surface of the plastic holder 12. This configuration allows the portable apparatus 1 having the appearance as beautiful as the conventional one that made of reinforced glass layer. Besides, the touch control function of the portable apparatus 1 is as well as the conventional one. Moreover, the invention is benefit in that the plastic holder 12 has sufficient strength and lower cost.

In summary, the portable apparatus of the invention is configured with a fixing area, and a plurality of first through holes and at least a second through hole are formed around the fixing area. The plastic holder is disposed at the fixing area and has a plurality of first pillars and at least a second pillar. The first pillars are correspondingly disposed through the first through holes, respectively, and the second pillar is correspondingly disposed through the second through hole. The touch pad is connected with the plastic holder. Accordingly, the portable apparatus of the invention is not configured with the conventional reinforced glass layer, but the appearance thereof is as simple and beautiful as the conventional art, while the touch control function thereof is the same as the conventional art. Moreover, the plastic holder has lower cost. As a result, the portable apparatus of the invention has lower cost but still has the same appearance and touch control function as the conventional click pad.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A portable apparatus, comprising:
a casing having a fixing area, wherein a plurality of first through holes and at least a second through hole are formed around the fixing area;
a plastic holder disposed at the fixing area and having a plurality of first pillars and at least a second pillar, wherein the first pillars are correspondingly disposed through the first through holes, respectively, and the second pillar is correspondingly disposed through the second through hole; and
a touch pad connected with the plastic holder.

2. The portable apparatus of claim 1, wherein the first pillars and the second pillar are disposed on a bottom surface of the plastic holder.

3. The portable apparatus of claim 1, wherein the touch pad is connected to a bottom surface of the plastic holder.

4. The portable apparatus of claim 1, wherein the plastic holder is fastened to the casing via the first pillars by thermal bonding.

5. The portable apparatus of claim 1, wherein the fixing area further has an opening, and the first through holes and the second through hole are disposed adjacent to the opening.

6. The portable apparatus of claim 5, wherein the touch pad passes through the opening.

7. The portable apparatus of claim 1, which is an ultrabook, a notebook, a smart phone, a digital camera, a PDA, or a GPS.
